(19) United States
(12) Patent Application Publication
(10) Pub. No.: US 2026/0087194 A1
(43) Pub. Date: Mar. 26, 2026

(54) SELECTING A THERMODYNAMIC PROPERTY MODEL FOR AN INDUSTRIAL PROCESS

(71) Applicant: Honeywell International Inc., Charlotte, NC (US)

(72) Inventors: Rahul AS, Bengaluru (IN); Hari Prasad Nandyala, Bengaluru (IN); Niraj Thakre, Bengaluru (IN); Jami Srinu, Bengaluru (IN)

(21) Appl. No.: 18/895,710

(22) Filed: Sep. 25, 2024

(51) Int. Cl. G06F 30/17; G06F 30/27

(52) U.S. Cl. CPC G06F 30/17; G06F 30/27

(57) ABSTRACT

Devices, methods, and systems for selecting a thermodynamic property model for an industrial process are described herein. One method includes receiving data comprising current operating parameter information for an industrial process, inputting the data and historical operating parameter information for the industrial process to an artificial neural network (ANN), selecting, via the ANN, a thermodynamic property model for simulating the industrial process based on the data and the historical operating parameter information, and simulating the industrial process utilizing the current operating parameter information and the selected thermodynamic property model.

### TECHNICAL FIELD

The present disclosure relates generally to devices, methods, and systems for selecting a thermodynamic property model for an industrial process.

### BACKGROUND

Process simulation for an industrial process can be a model-based representation of the industrial process, such as a chemical, physical, biological, and/or other process and associated unit operations. By utilizing chemical and physical properties of components and mixtures, reactions, and/or mathematical models, a process simulation can determine mass and/or energy balances of an industrial process, as well as determine thermophysical properties involved in the industrial process. The process simulation can be used to determine optimal conditions for a simulated industrial process.

### BRIEF DESCRIPTION OF THE DRAWINGS

FIG. 1 illustrates an example of a method for selecting a thermodynamic property model for an industrial process via an artificial neural network in accordance with one or more embodiments.

FIG. 2 illustrates an example of a method for training an artificial neural network to select a thermodynamic property model for an industrial process in accordance with one or more embodiments.

FIG. 3 illustrates an example of a decision tree for selecting a thermodynamic property model to train an artificial neural network in accordance with one or more embodiments.

FIG. 4 illustrates an example of experimental process data included in historical operating parameter information in accordance with one or more embodiments.

FIG. 5 illustrates a data table having experimental process data and generated process data for an industrial process in accordance with one or more embodiments.

FIG. 6 is an example of a computing device for selecting a thermodynamic property model for an industrial process in accordance with one or more embodiments.

### DETAILED DESCRIPTION

Devices, methods, and systems for selecting a thermodynamic property model for an industrial process are described herein. One method includes receiving data comprising current operating parameter information for an industrial process, inputting the data and historical operating parameter information for the industrial process to an artificial neural network (ANN), selecting, via the ANN, a thermodynamic property model for simulating the industrial process based on the data and the historical operating parameter information, and simulating the industrial process utilizing the current operating parameter information and the selected thermodynamic property model.

As mentioned above, a process simulation can be utilized to determine thermophysical properties involved in an industrial process to determine optimal conditions (e.g., optimal operating conditions) for the industrial process. An industrial process can be a series of procedures involving chemical, physical, biological, electrical, and/or mechanical steps to aid in the generation of a product. For example, an industrial process may include solvent recovery, reactions (e.g., in a reactor), carbon capture processes, dehydrogenization, among other types of industrial processes.

A process simulation can utilize, for example, operating parameter information for the industrial process, as well as thermodynamic property models, to calculate certain properties (e.g., thermophysical properties) and/or other information for the industrial process. Operating parameter information can include the operating conditions for the industrial process and/or the component types of the industrial process. Additionally, thermodynamic property models can utilize mathematical models to perform thermodynamic calculations utilizing the operating parameter information for a particular industrial process. As such, the process simulation can accurately model and select real-world operating conditions for the physical industrial process that can provide an optimal efficiency for the physical industrial process.

During the process simulation setup, current operating parameter information can be known. For example, during a solvent recovery process, the chemical compounds included in the solvent recovery process, a current temperature, and a current pressure for the solvent recovery process can be known parameters. For the process simulation, a thermodynamic property model has to be selected.

A large number of thermodynamic property models exist that can be selected. For example, there may be a first subset of thermodynamic property models specifically utilized in solvent recovery processes, a second subset of thermodynamic property models specifically utilized in dehydrogenization processes, a third subset of thermodynamic property models for carbon capture processes, etc. These thermodynamic property models can be different for different industrial processes, as they utilize different mathematical models and equations due to the different industrial processes having different thermodynamic properties. For example, the chemical and physical component properties for a dehydrogenization process are different from the chemical and physical component properties for a carbon capture process. Therefore, different thermodynamic property models are utilized to describe various different industrial processes.

Accordingly, it can be important to select the correct thermodynamic property model for a particular process simulation. In previous approaches, the thermodynamic property model would have to be manually selected by a decision tree process utilizing the current operating parameter information for the particular industrial process. The decision tree may lead to one or a group of thermodynamic property models that might work for the particular industrial process. However, some thermodynamic property models in the group determined via decision trees may not accurately reflect the conditions for the industrial process. Accordingly, such an approach can lead to inaccuracies that can cause operational inefficiencies due to wasted resources, rework, and process downtime, leading to financial losses. These inaccuracies can also discourage the use of process simulations.

Embodiments of the present disclosure, however, can select a thermodynamic property model for an industrial process via a neural network that can be trained to select a thermodynamic property model for use in a process simulation based on current operating parameter information. Such an approach can automate the selection of thermodynamic property models for a user, increasing accuracy in process simulation outcomes, as well as reducing time and effort of a user in having to manually select a thermodynamic property model. For example, for a given industrial process, current operating parameter information and historical operating parameter information can be provided to an artificial neural network (ANN), and the ANN can select a proper thermodynamic property model for simulating the industrial process and generating a flow sheet for the industrial process.

The ANN can be trained by utilizing existing thermodynamic property models, and historical and experimental data available from open literature. For a given industrial process, data describing the industrial process can be generated across ranges of operating parameters for corresponding selected thermodynamic property models. This data can be generated by calculating data from the selected thermodynamic property models across the ranges of the operating parameters. This data can undergo preprocessing, including being compared against pre-generated experimental data (e.g., published, academic data for various industrial processes across ranges of operating parameters) to determine a deviation of the generated process data from the experimental data. The thermodynamic property model having the lowest deviation can be selected, and this process can be iterated across a number of thermodynamic property models for different industrial processes across different ranges of operating parameters (e.g., chemical components, temperatures, and pressures) to develop the neural network framework of the ANN.

Accordingly, once the ANN is trained and developed, current operating parameter information for an industrial process can be provided to the ANN, and the ANN can automatically select a thermodynamic property model for an industrial process. The selected thermodynamic property model and the current operating parameter information can be utilized to simulate the industrial process and to generate a flowsheet for the industrial process. The flowsheet can operate as a diagrammatic model of the industrial process that can illustrate the arrangement of the equipment of the operating process and/or stream connections between the equipment and operation conditions of the process, for example. The ease and accuracy of automatic selection of the thermodynamic property model using the ANN can allow for more accurate thermodynamic property model selection, avoiding inaccuracies and allowing for a more optimized industrial process as compared with previous approaches.

In the following detailed description, reference is made to the accompanying drawings that form a part hereof. The drawings show by way of illustration how one or more embodiments of the disclosure may be practiced.

These embodiments are described in sufficient detail to enable those of ordinary skill in the art to practice one or more embodiments of this disclosure. It is to be understood that other embodiments may be utilized and that mechanical, electrical, and/or process changes may be made without departing from the scope of the present disclosure.

As will be appreciated, elements shown in the various embodiments herein can be added, exchanged, combined, and/or eliminated so as to provide a number of additional embodiments of the present disclosure. The proportion and the relative scale of the elements provided in the figures are intended to illustrate the embodiments of the present disclosure and should not be taken in a limiting sense.

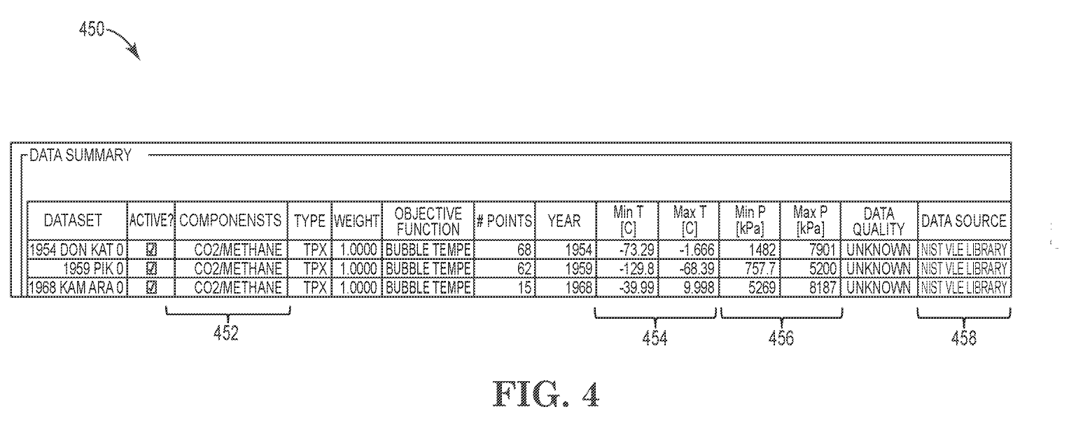

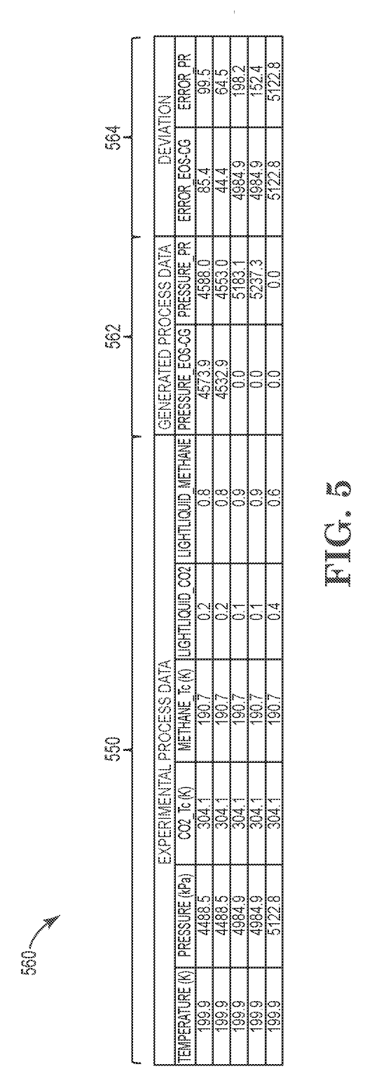

The figures herein follow a numbering convention in which the first digit or digits correspond to the drawing figure number and the remaining digits identify an element or component in the drawing. Similar elements or components between different figures may be identified by the use of similar digits. For example, 450 may reference element “50” in FIG. 4, and a similar element may be referenced as 550 in FIG. 5.

As used herein, “a”, “an”, or “a number of” something can refer to one or more such things, while “a plurality of” something can refer to more than one such things. For example, “a number of components” can refer to one or more components, while “a plurality of components” can refer to more than one component.

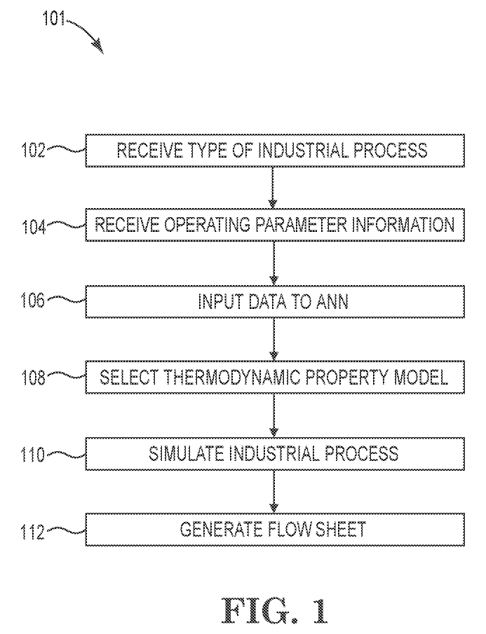

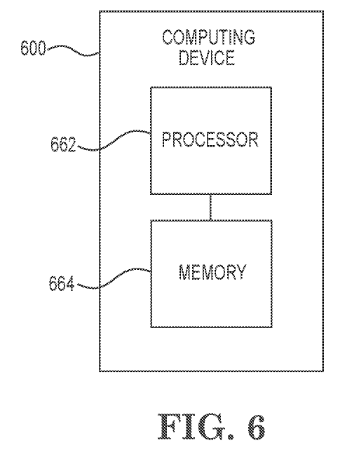

FIG. 1 illustrates an example of a method 101 for selecting a thermodynamic property model for an industrial process via an artificial neural network in accordance with one or more embodiments. The method 101 can be performed by, for example, computing device 600, further described in connection with FIG. 6.

As mentioned above, a process simulation can utilize operating parameter information for an industrial process and a thermodynamic property model to calculate properties for the industrial process. For example, the industrial process may be a solvent recovery process. The properties for the industrial process the process simulation can calculate may include a bubble point, dew point, theoretical number of plates for a separation, sensible heat values, heat of vaporization values, etc. The thermodynamic property model can include mathematical models to perform thermodynamic calculations for the above properties for the solvent recovery process, as one example.

In order for the process simulation to accurately model the physical industrial process, a thermodynamic property model has to be selected for use with the operating parameter information for the industrial process. Based on the type of industrial process and the operating parameter information, a computing device can automatically select a thermodynamic property model via an artificial neural network (ANN), as is further described herein.

Accordingly, the method 101 can be utilized to select a thermodynamic property model. At 102, the computing device can receive data comprising a type of industrial process. As described above, an industrial process can be a series of procedures involving chemical, physical, biological, electrical, and/or mechanical steps to aid in the generation of a product. For example, an industrial process may include a solvent recovery process, reactions (e.g., in a reactor), carbon capture processes, and/or dehydrogenization, among other types of industrial processes.

The received data (e.g., the type of industrial process) can be, for instance, a solvent recovery process. The type of industrial process (e.g., a solvent recovery process) may be selected by, for example, a user from a plurality of industrial process types (e.g., reactions, carbon capture processes, dehydrogenization, etc.).

At 104, the computing device can receive data comprising current operating parameter information for the industrial process. Operating parameter information can include a component type of the industrial process and/or current operating conditions for the industrial process. Operating conditions can include a temperature and/or a pressure for the industrial process. A component type can include a chemical compound utilized in the industrial process.

For example, a user can select a component type for the industrial process, such as a pure component (e.g., CO₂, Methane, Argon, Nitrogen, etc.) and/or chemical compound (e.g., binary mixtures such as CO₂/Methane, Methane/Argon, Methane/Nitrogen, etc.). Types of chemical components and/or compounds can include hydrocarbons, solids, amines, alcohols, ketones, and/or other suitable types of chemical components and/or compounds for a particular industrial process.

Additionally, a user can select current operating conditions for the industrial process. Current operating conditions for the industrial process can include a current temperature (e.g., -30.3 °C) and/or a current pressure (e.g., 5,243 kilopascals (kPa)) for the industrial process. In some examples, the current operating conditions can include ranges of current temperatures and pressures. For example, the user may select a range of current temperatures (e.g., -73.29 °C to -1.66 °C) and/or a range of current pressures (e.g., 1,482 kPa to 7,901 kPa).

At 106, the computing device can input the received data (e.g., the selected type of industrial process (e.g., a solvent recovery process) as well as the current operating parameter information (e.g., current temperature and current pressure) to an ANN. Artificial neural networks (ANNs) are networks that can process information by modeling a network of neurons. The network of neurons can be modeled in such a way so as to process information. For example, ANNs can include a multiple neuron topology, which can be referred to as artificial neurons or units. An ANN operation refers to an operation that processes inputs using units to perform a given task.

The ANN operation may involve applying various machine learning algorithms to process inputs. For example, the ANN can perform machine learning tasks by performing a weighted combination of inputs (either from a network input or a previous layer) at each unit to generate an output. The probability weight associations can be provided by a plurality of units that comprise the ANN. The units together with weights, biases, embeddings, and/or activation functions can be used to generate an output of the ANN based on the input to the ANN. Units of the ANN can be grouped to form layers of the ANN. The ANN can implement or represent an algorithm consisting of a series of connected layers that process signals based on outputs from other ones of the series of connected layers.

For example, the computing device can provide the inputs including the type of industrial process and the current operating parameter information to the ANN, and the ANN can select the thermodynamic property model at 108 based on the inputs. For instance, the ANN can utilize the various layers within the ANN (e.g., and the units located therein) to process the type of industrial process and the current operating parameter information by applying activation functions to inputs to the layers of the ANN. The activation functions can transform the inputs to the layers into outputs that can be passed on to successive layers until the ANN can ultimately output (e.g., select) a thermodynamic property model from a plurality of thermodynamic property models for simulating the industrial process. The ANN can be trained via training data to select a particular thermodynamic property model utilizing the type of industrial process and the current operating parameter information, as is further described herein.

The plurality of thermodynamic property models can be preexisting models used for different industrial processes and/or operating parameter information. For example, in a solvent recovery process, a Peng-Robinson thermodynamic property model may be generally utilized, whereas for particular temperature, pressure, and component types (e.g., heavy hydrocarbons), a Chao-Seader thermodynamic property model may be utilized.

However, while various examples of thermodynamic property models are given above for a solvent recovery process, embodiments are not so limited. For example, a different industrial process, such as dehydrogenization, may utilize different thermodynamic property models based on the operating parameter information (e.g., component type and temperature and/or pressure) for that industrial process.

At 110, the computing device can simulate the industrial process utilizing the current operating parameter information and the selected thermodynamic property model from the ANN. Simulating the industrial process can include determining thermophysical properties involved in the industrial process to determine optimal conditions for the industrial process. The process simulation can provide simulated thermodynamic modeling of component types involved in the industrial process, transport properties (e.g., properties that describe the movement or transfer of different quantities such as matter, momentum, electrical charge, and/or heat energy through a medium) of components, process conditions, mass flow rates, energy and/or material balances, and/or other information associated with the industrial process.

At 112, the computing device can generate a flow sheet for the industrial process based on the simulated industrial process. For example, the computing device can generate a flow sheet for a solvent recovery process based on the simulated solvent recovery process utilizing the provided operating parameter information to the ANN and the thermodynamic property model selected by the ANN for the solvent recovery process.

In some examples, the flow sheet can include a simulated mass balance and/or a simulated energy balance for an energy flow in the industrial process. The simulated mass and/or energy balances can be based on the thermodynamic property model selected by the ANN and the current operating parameter information provided as an input. For example, the simulated mass balance for the solvent recovery process can provide an estimation of the material provided to the solvent recovery equipment and the material exiting the solvent recovery equipment. Similar information can be estimated related to the energy provided to the solvent recovery equipment and that exiting the solvent recovery equipment for a simulated energy balance.

In some examples, the flow sheet can further illustrate an arrangement of equipment for the industrial process and/or connections between the equipment for the industrial process. For example, the flow sheet can illustrate material provided to solvent recovery equipment, an energy source to the solvent recovery equipment, a condensing unit, product and/or waste leaving the solvent recovery equipment, pumps configured to move the material to the solvent recovery equipment, remove product and/or waste from the solvent recovery equipment, and/or connections that may exist between such equipment, among other examples of equipment arrangement in different industrial processes.

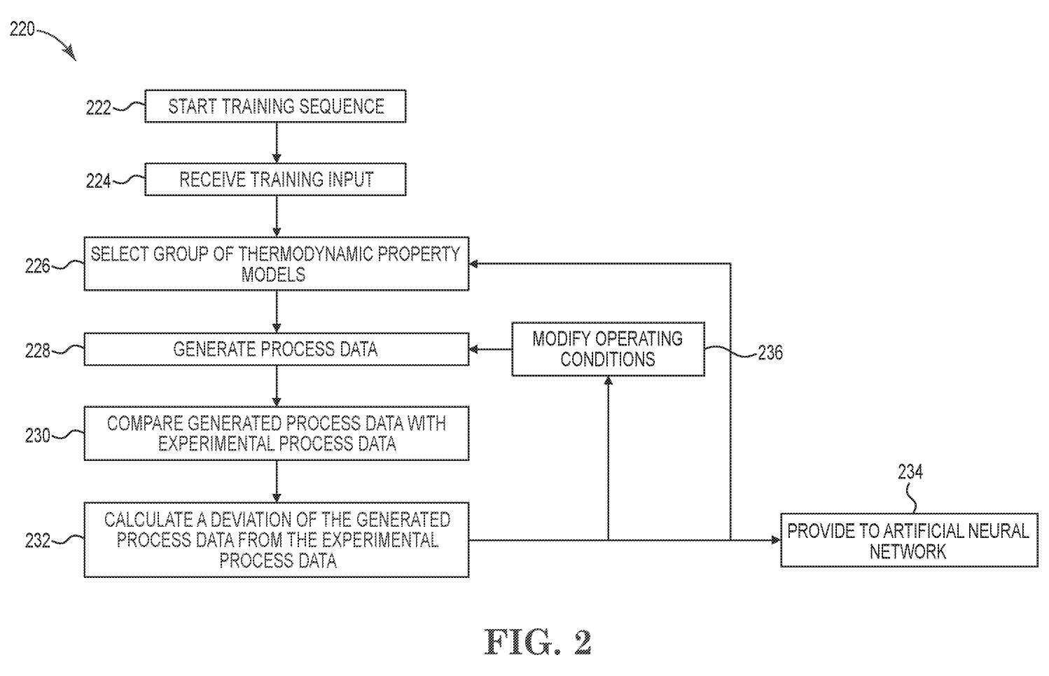

As mentioned above, the ANN can be trained to select a thermodynamic property model. The ANN can be trained utilizing historical operating parameter information to select a thermodynamic property model, as is further described in connection with FIG. 2.

FIG. 2 illustrates an example of a method 220 for training an artificial neural network to select a thermodynamic property model for an industrial process in accordance with one or more embodiments. The method 220 can be performed by, for example, computing device 600, further described in connection with FIG. 6.

As previously described in connection with FIG. 1, the computing device can select, via an ANN, a thermodynamic property model for use in a process simulation. The process simulation can utilize the selected thermodynamic property model, as well as current operating parameter information such as operating conditions of the industrial process (e.g., temperature and/or pressure) and component information for the industrial process (e.g., chemical component types involved in the industrial process), to determine thermophysical properties involved in the industrial process, as described above.

However, the ANN has to be trained in order to accurately select a thermodynamic property model. Training the ANN is further described herein.

The ANN can be trained to select the thermodynamic property model by training regression models for a plurality of thermodynamic property models to determine a deviation of each thermodynamic property model from historical data. For example, each thermodynamic property model can generate process data (e.g., generated temperature and pressure data) over ranges of different input operating parameter information (e.g., over ranges of different operating conditions such as temperature and pressure and for different chemical component types) for comparison against predetermined experimental process data. A comparison of the generated process data can be made against the predetermined experimental process data, and the thermodynamic property model having the lowest deviation from the predetermined experimental process data can be selected (e.g., classified) by the ANN. This process can be iterated for different thermodynamic property models across ranges of different input operating conditions to train the ANN according to the method 220, as is further described herein.

At 222, the method 220 can begin by starting the training sequence for the ANN. Various regression models to predict errors for each thermodynamic property model can be generated, and the ANN can be trained as a classification model to predict (e.g., select) an optimal thermodynamic property model based on input information and deviation (e.g., predicted error) from predetermined experimental process data.

To begin the training sequence, the computing device can receive, at 224, a training input. The training input can include historical operating parameter information including experimental process data. Additionally, the training input can further include an input similar to the operating parameter information and can include a component type and first sample operating conditions for the component type. For example, the component type can be CO₂/Methane binary component mixture, and the first sample operating conditions for the CO₂/Methane binary component mixture can be a temperature of 199.9 Kelvin (K) and a pressure of 4,488.5 kPa.

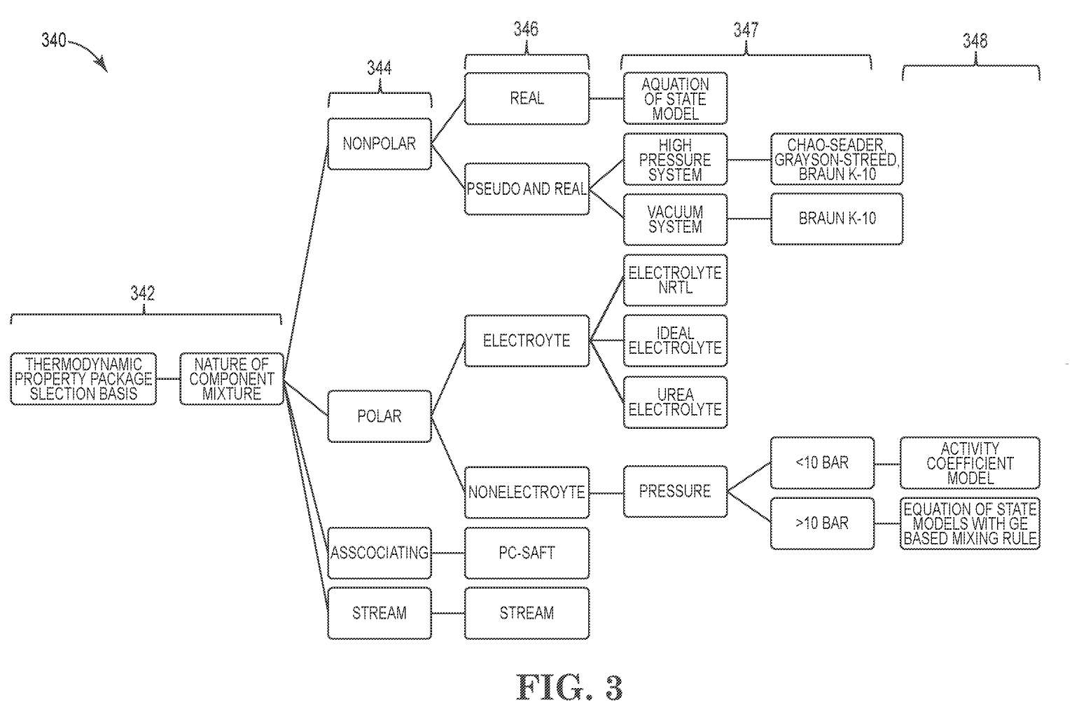

At 226, the method can include selecting an initial group of thermodynamic property models from a plurality of thermodynamic property models based on the component type and the first sample operating conditions. For example, the computing device can select the Equations of State (EOS) Combustion Gases (EOS-CG) thermodynamic property model and a Peng-Robinson (PR) thermodynamic property model based on the CO₂/Methane binary component mixture and the temperature of 199.9 K and pressure of 4,488.5 kPa. The computing device can select the initial group of thermodynamic property models according to pre-existing decision trees, as is further described in connection with FIG. 3.

At 228, the computing device can generate process data for the industrial process using the initial group of thermodynamic property models and the first sample operating conditions. For example, for a solvent recovery process, the computing device can determine the pressure for the solvent recovery process utilizing the EOS-CG thermodynamic property model (e.g., and first sample operating conditions of 199.9 K and 4,488.5 kPa) to be 4,573.9 kPa. Additionally, the computing device can determine the pressure for the solvent recovery process utilizing the PR thermodynamic property model (e.g., and first sample operating conditions of 199.9 K and 4,488.5 kPa) to be 4,588.0 kPa.

At 230, the method can include comparing the generated process data from the initial group of thermodynamic property models with predetermined experimental operating parameter information included in the historical operating parameter information. As mentioned above, the generated process data utilizing the EOS-CG thermodynamic property model resulted in a pressure of 4,573.9 kPa. The generated pressure of 4,573.9 kPa can be compared against predetermined experimental operating parameter information (e.g., 4,488.5 kPa, utilized as the first sample operating condition along with the temperature of 199.9 K). Additionally, the generated process data utilizing the PR thermodynamic property model resulted in a pressure of 4,588.0 kPa, which can be compared against predetermined experimental operating parameter information (e.g., 4,488.5 kPa, utilized as the first sample operating condition along with the temperature of 199.9 K).

At 232, the method includes calculating a deviation of the generated process data from the initial group of thermodynamic property models from the predetermined experimental process data. With respect to the EOS-CG thermodynamic property model, which resulted in a pressure of 4,573.9 kPa as compared to the predetermined experimental process data of 4,488.5 kPa, the computing device can calculate a deviation of the generated process data from the predetermined experimental process data of 85.4 kPa. With respect to the PR thermodynamic property model, which resulted in a pressure of 4,588.0 kPa as compared to the predetermined experimental process data of 4,488.5 kPa, the computing device can calculate a deviation of the generated process data from the predetermined experimental process data of 99.5 kPa.

Accordingly, as illustrated above, the EOS-CG thermodynamic property model resulted in a deviation (e.g., of 85.4 kPa) from the predetermined experimental process data that is less than the deviation of the PR thermodynamic property model (e.g., of 99.5 kPa) for the given first sample operating conditions (e.g., 199.9 K temperature and 4,488.5 kPa pressure). The computing device can, therefore, select the EOS-CG thermodynamic property model from the initial group of thermodynamic property models (e.g., EOS-CG and PR) as a result of the EOS-CG thermodynamic property model having generated process data with a lower deviation from the predetermined experimental process data. The computing device can provide the historical operating parameter information including experimental process data and the result to the ANN at 234.

Although the method 220 is described above as determining a deviation of generated process data from a group of thermodynamic property models for one set of sample operating conditions, embodiments are not so limited. For example, the computing device can train the ANN to select a thermodynamic property model for an industrial process by determining a deviation of generated process data from an initial group of thermodynamic property models across a range of operating conditions.

For example, at 236, the computing device can modify the sample operating conditions from the first sample operating conditions to a second sample operating conditions. The second sample operating conditions can be, for instance, 199.5 K temperature and 4624.5 kPa. The computing device can repeat the method 220 utilizing the EOS-CG thermodynamic property model and the PR thermodynamic property model for the second sample operating conditions.

For example, for a solvent recovery process, the computing device can determine the pressure for the solvent recovery process utilizing the EOS-CG thermodynamic property model (e.g., and second sample operating conditions of 199.9 K and 4,501.5 kPa) to be 4,532.9 kPa. Additionally, the computing device can determine the pressure for the solvent recovery process utilizing the PR thermodynamic property model (e.g., and second sample operating conditions of 199.9 Kelvin (K) and 4,501.5 kPa) to be 4,553.0 kPa.

At 230, the method can include comparing the generated process data from the initial group of thermodynamic property models with predetermined experimental operating parameter information included in the historical operating parameter information. As mentioned above, the generated process data utilizing the EOS-CG thermodynamic property model resulted in a pressure of 4,532.9 kPa. The generated pressure of 4,532.9 kPa can be compared against predetermined experimental operating parameter information (e.g., 4,501.5 kPa, utilized as the first sample operating condition along with the temperature of 199.9 K). Additionally, the generated process data utilizing the PR thermodynamic property model resulted in a pressure of 4,553.0 kPa, which can be compared against predetermined experimental operating parameter information (e.g., 4,501.5 kPa, utilized as the first sample operating condition along with the temperature of 199.9 K).

At 232, the method includes calculating a deviation of the generated process data from the initial group of thermodynamic property models from the predetermined experimental process data. With respect to the EOS-CG thermodynamic property model, which resulted in a pressure of 4,532.9 kPa as compared to the predetermined experimental process data of 4,501.5 kPa, the computing device can calculate a deviation of the generated process data from the predetermined experimental process data of 31.4 kPa. With respect to the PR thermodynamic property model, which resulted in a pressure of 4,553.0 kPa as compared to the predetermined experimental process data of 4,501.5 kPa, the computing device can calculate a deviation of the generated process data from the predetermined experimental process data of 51.5 kPa.

Accordingly, as illustrated above, the EOS-CG thermodynamic property model resulted in a deviation (e.g., of 31.4 kPa) from the predetermined experimental process data that is less than the deviation of the PR thermodynamic property model (e.g., of 51.5 kPa) for the given first sample operating conditions (e.g., 199.9 K temperature and 4,501.5 kPa pressure). The computing device can, therefore, select the EOS-CG thermodynamic property model from the initial group of thermodynamic property models (e.g., EOS-CG and PR) as a result of the EOS-CG thermodynamic property model having generated process data with a lower deviation from the predetermined experimental process data. The computing device can provide the result to the ANN at 234.

The computing device can iterate the method 220 across a range of different temperatures (e.g., 199.9 K to 223.7 K) and pressures (1,482.4 kPa to 6,425.9 kPa). Additionally, the method 220 can be iterated across different combinations of said temperatures and pressures within said ranges for the group of thermodynamic property models. Accordingly, the method 220 can result in robust training data for the ANN regarding different sample operating conditions for the selected group of thermodynamic property models (e.g., EOS-CG and PR).

However, as mentioned above, the ANN can be trained with different sample operating conditions, ranges of sample operating conditions, and/or combinations of said temperatures and pressures within said ranges for different groups of thermodynamic property models. That is, the computing device can further train the ANN to select the thermodynamic property model for an industrial process by determining a deviation of generated process data from different groups of thermodynamic property models.

For example, the method 220 can be further repeated by selecting, at 226, a Chao-Seader (CS) thermodynamic property model and the PR thermodynamic property model based on the CO₂/Methane binary component mixture and the temperature of 199.9 K and pressure of 4,488.5 kPa.

At 228, the computing device can generate process data for the industrial process using the initial group of thermodynamic property models and the sample operating conditions. For example, for the solvent recovery process, the computing device can determine the pressure for the solvent recovery process utilizing the CS thermodynamic property model (e.g., and sample operating conditions of 199.9 K and 4,488.5 kPa) to be 4,542.9 kPa. Additionally, the computing device can determine the pressure for the solvent recovery process utilizing the PR thermodynamic property model (e.g., and sample operating conditions of 199.9 K and 4,488.5 kPa) to be 4,588.0 kPa.

At 230, the method can include comparing the generated process data from the initial group of thermodynamic property models with predetermined experimental operating parameter information included in the historical operating parameter information. As mentioned above, the generated process data utilizing the CS thermodynamic property model resulted in a pressure of 4,542.9 kPa. The generated pressure of 4,542.9 kPa can be compared against predetermined experimental operating parameter information (e.g., 4,488.5 kPa, utilized as the sample operating condition along with the temperature of 199.9 K). Additionally, the generated process data utilizing the PR thermodynamic property model resulted in a pressure of 4,588.0 kPa, which can be compared against predetermined experimental operating parameter information (e.g., 4,488.5 kPa, utilized as the first sample operating condition along with the temperature of 199.9 K).

At 232, the method includes calculating a deviation of the generated process data from the initial group of thermodynamic property models from the predetermined experimental process data. With respect to the CS thermodynamic property model, which resulted in a pressure of 4,542.9 kPa as compared to the predetermined experimental process data of 4,488.5 kPa, the computing device can calculate a deviation of the generated process data from the predetermined experimental process data of 54.4 kPa. With respect to the PR thermodynamic property model, which resulted in a pressure of 4,588.0 kPa as compared to the predetermined experimental process data of 4,488.5 kPa, the computing device can calculate a deviation of the generated process data from the predetermined experimental process data of 99.5 kPa.

Accordingly, as illustrated above, the CS thermodynamic property model resulted in a deviation (e.g., of 54.4 kPa) from the predetermined experimental process data that is less than the deviation of the PR thermodynamic property model (e.g., of 99.5 kPa) for the given sample operating conditions (e.g., 199.9 K temperature and 4,488.5 kPa pressure). The computing device can, therefore, select the CS thermodynamic property model from the initial group of thermodynamic property models (e.g., CS and PR) as a result of the CS thermodynamic property model having generated process data with a lower deviation from the predetermined experimental process data. The computing device can provide the result to the ANN at 234. Additionally, at 236, the method 220 can again be repeated across different operating conditions for the CS and PR thermodynamic property models.

Although the method 220 is described above as being performed for a CO₂/Methane binary component mixture and EOS-CG, PR, and CS thermodynamic property models, embodiments of the disclosure are not so limited. For example, any other suitable component type (e.g., chemicals, chemical compounds, etc.) can be utilized with other thermodynamic property models in order to train the ANN.

FIG. 3 illustrates an example of a decision tree 340 for selecting a thermodynamic property model to train an artificial neural network in accordance with one or more embodiments. Decision tree 340 can be used by, for example, computing device 600, further described in connection with FIG. 6.

As previously described in connection with FIG. 2, the computing device can select, at step 342 of the decision tree 340, an initial group of thermodynamic property models from a plurality of thermodynamic property models. The initial group can be selected based on the component type and sample operating conditions. As an example, the component type can be a particular chemical compound and the industrial process involves a particular pressure greater than 10 bar.

The computing device can further determine, at step 344 of the decision tree 340 in this example, that the particular chemical compound has a polar chemical structure, and is a non-electrolyte at step 346 of the decision tree. At step 347 of the decision tree 340 the computing device can determine a pressure of the particular industrial process is greater than 10 bar, and at step 348 of decision tree 340 the computing device can select an Equation of State thermodynamic property model.

As a further example, the computing device can select, at step 342 of decision tree 340, an initial group of thermodynamic property models from a plurality of thermodynamic property models. The computing device can further determine, at step 344 of decision tree 340 in this example, that the particular chemical compound has a polar chemical structure, and determine the particular chemical compound is an electrolyte at step 346 of the decision tree 340. At step 347 of decision tree 340, the computing device can select either an Electrolyte NRTL, Ideal Electrolyte, or Urea Electrolyte thermodynamic property model.

The thermodynamic property model selected according to the decision tree 340 can be utilized in the training process as previously described in connection with FIG. 2. For instance, in the second example, the Electrolyte NRTL, Ideal Electrolyte, and/or Urea Electrolyte thermodynamic property models can be utilized, process data can be generated across different operating conditions, the generated process data can be compared with experimental process data, and a deviation of the generated process data from the experimental process data can be determined and provided to the ANN to train the ANN.

FIG. 4 illustrates an example of experimental process data 450 included in historical operating parameter information in accordance with one or more embodiments. The experimental process data 450 can be included in historical operating parameter information and can be compared against generated process data as previously described in connection with FIG. 2.

As illustrated in FIG. 4, the experimental process data 450 can be for component type 452, a CO₂/Methane binary mixture. The experimental process data 450 can be defined by temperature range 454 and pressure range 456, and can include an associated data source 458.

For example, the dataset titled “1954 don kat 0” can include the CO₂/Methane binary mixture, be defined by the temperature range 454 between -73.29 C and -1.66 C and the pressure range 456 between 1,482 kPa and 7,901 kPa. Additionally, the “1954 don kat 0” can be a dataset having a data source 458 from the National Institute of Standards and Technology (NIST) Vapor-Liquid Equilibrium (VLE) Library. Such data can be compared against generated process data as previously described in connection with FIG. 2.

FIG. 5 illustrates a data table 560 having experimental process data 550 and generated process data 562 for an industrial process in accordance with one or more embodiments. As illustrated in FIG. 5, experimental process data 550 can be shown against generated process data and calculated deviation therebetween.

For instance, as previously described in connection with FIG. 2, process data 562 can be generated for an industrial process using a group of thermodynamic property models and sample operating conditions. For example, the group of thermodynamic property models can include EOS-CG and PR thermodynamic property models, and the computing device can generate process utilizing the EOS-CG and PR thermodynamic property models according to sample operating conditions. For example, based on sample operating conditions of 199.9 K and 4,488.5 kPa, process data 562 including a pressure of 4,573.9 kPa can be generated using the EOS-CG thermodynamic property model and a pressure of 4,588.0 kPa can be generated using the PR thermodynamic property model.

The generated process data from the EOS-CG and PR thermodynamic property models can be compared with experimental process data 550. For example, the pressure determined from the EOS-CG thermodynamic property model (e.g., 4,573.9 kPa) and the PR thermodynamic property model (4,588.0 kPa) can be compared with the pressure in the experimental process data 550 (e.g., 4,488.5 kPa).

Additionally, a deviation 564 of the generated process data 562 from the group of thermodynamic property models from the experimental process data 550 can be calculated. For example, the deviation of the pressure generated by the EOS-CG thermodynamic property model from the experimental process data 550 is 85.4 kPa, as illustrated in FIG. 5. Additionally, the deviation of the pressure generated by the PR thermodynamic property model from the experimental process data 550 is 99.5 kPa, as illustrated in FIG. 5.

Accordingly, the EOS-CG thermodynamic property model can be selected over the PR thermodynamic property model for particular operating conditions of 199.9 K and 4,488.5 kPa for the CO₂/Methane binary mixture. As previously described in connection with FIG. 2, this method can be iterated over different sample operating conditions, different component types, different thermodynamic property models, etc.

Accordingly, selecting a thermodynamic property model for an industrial process, as described herein, can allow for automation of selection of a thermodynamic property model for use in a process simulation. Such an approach can reduce time and effort of a user in having to manually select a thermodynamic property model, ultimately increasing accuracy in process simulation outcomes. Accordingly, the streamlined process simulation can result in a more optimized industrial process as compared with previous approaches.

FIG. 6 is an example of a computing device 600 for selecting a thermodynamic property model for an industrial process, in accordance with one or more embodiments of the present disclosure. As illustrated in FIG. 6, the computing device 600 can include a memory 664 and a processor 662 for selecting a thermodynamic property model for an industrial process, in accordance with the present disclosure.

The memory 664 can be any type of storage medium that can be accessed by the processor 662 to perform various examples of the present disclosure. For example, the memory 664 can be a non-transitory computer readable medium having computer readable instructions (e.g., executable instructions/computer program instructions) stored thereon that are executable by the processor 662 for selecting a thermodynamic property model for an industrial process in accordance with the present disclosure.

The memory 664 can be volatile or nonvolatile memory. The memory 664 can also be removable (e.g., portable) memory, or non-removable (e.g., internal) memory. For example, the memory 664 can be random access memory (RAM) (e.g., dynamic random access memory (DRAM) and/or phase change random access memory (PCRAM)), read-only memory (ROM) (e.g., electrically erasable programmable read-only memory (EEPROM) and/or compact-disc read-only memory (CD-ROM)), flash memory, a laser disc, a digital versatile disc (DVD) or other optical storage, and/or a magnetic medium such as magnetic cassettes, tapes, or disks, among other types of memory.

Further, although memory 664 is illustrated as being located within computing device 600, embodiments of the present disclosure are not so limited. For example, memory 664 can also be located internal to another computing resource (e.g., enabling computer readable instructions to be downloaded over the Internet or another wired or wireless connection).

The processor 662 may be a central processing unit (CPU), a semiconductor-based microprocessor, and/or other hardware devices suitable for retrieval and execution of machine-readable instructions stored in the memory 664.

Although specific embodiments have been illustrated and described herein, those of ordinary skill in the art will appreciate that any arrangement calculated to achieve the same techniques can be substituted for the specific embodiments shown. This disclosure is intended to cover any and all adaptations or variations of various embodiments of the disclosure.

It is to be understood that the above description has been made in an illustrative fashion, and not a restrictive one. Combination of the above embodiments, and other embodiments not specifically described herein will be apparent to those of skill in the art upon reviewing the above description.

The scope of the various embodiments of the disclosure includes any other applications in which the above structures and methods are used. Therefore, the scope of various embodiments of the disclosure should be determined with reference to the appended claims, along with the full range of equivalents to which such claims are entitled.

In the foregoing Detailed Description, various features are grouped together in example embodiments illustrated in the figures for the purpose of streamlining the disclosure. This method of disclosure is not to be interpreted as reflecting an intention that the embodiments of the disclosure require more features than are expressly recited in each claim.

Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
receiving, by a computing device, data comprising current operating parameter information for an industrial process;
inputting, by the computing device, the data and historical operating parameter information for the industrial process to an artificial neural network (ANN);
selecting, via the ANN, a thermodynamic property model for simulating the industrial process based on the data and the historical operating parameter information; and
simulating, by the computing device, the industrial process utilizing the current operating parameter information and the selected thermodynamic property model.

2. The method of claim 1, wherein the method includes generating, by the computing device based on the simulated industrial process, a flow sheet for the industrial process.

3. The method of claim 1, wherein the method includes training the ANN using the historical operating parameter information to select a thermodynamic property model.

4. The method of claim 1, wherein the method includes receiving, by the computing device, a selection of the industrial process from a plurality of industrial processes.

5. The method of claim 1, wherein the current operating parameter information includes:
a component type of the industrial process; and
current operating conditions for the industrial process.

6. The method of claim 5, wherein the component type includes a chemical compound for the industrial process.

7. The method of claim 5, wherein the current operating conditions for the industrial process include a current temperature and a current pressure for the industrial process.

8. The method of claim 1, wherein the method includes selecting, by the computing device via the ANN, the thermodynamic property model from a plurality of thermodynamic property models.

9. A non-transitory computer-readable medium storing instructions executable by a processing resource to cause the processing resource to:
receive data comprising a type of industrial process and current operating parameter information for the industrial process;
input the data and historical operating parameter information for the industrial process to an artificial neural network (ANN);
select, via the ANN, a thermodynamic property model from a plurality of thermodynamic property models for simulating the industrial process based on the data and the historical operating parameter information;
simulate the industrial process utilizing the current operating parameter information and the selected thermodynamic property model from the ANN; and
generate a flow sheet for the industrial process based on the simulated industrial process.

10. The non-transitory computer-readable medium of claim 9, comprising instructions train the ANN to select a thermodynamic property model for the industrial process by receiving a training input including a component type and first sample operating conditions for the component type.

11. The non-transitory computer-readable medium of claim 10, comprising instructions to select an initial group of thermodynamic property models from a plurality of thermodynamic property models based on the component type and the first sample operating conditions.

12. The non-transitory computer-readable medium of claim 11, comprising instructions to generate process data for the industrial process using the initial group of thermodynamic property models.

13. The non-transitory computer-readable medium of claim 12, comprising instructions to:
compare the generated process data from the initial group of thermodynamic property models with predetermined experimental process data included in the historical operating parameter information; and
calculate a deviation of the generated process data from the initial group of thermodynamic property models from the predetermined experimental process data.

14. The non-transitory computer-readable medium of claim 13, comprising instructions to select a thermodynamic property model from the initial group of thermodynamic property models having generated process data with a lowest deviation from the predetermined experimental process data.

15. The non-transitory computer-readable medium of claim 11, including instructions to train the ANN to select the thermodynamic property model for the industrial process by determining a deviation of generated process data from the initial group of thermodynamic property models across a range of operating conditions.

16. The non-transitory computer-readable medium of claim 11, including instructions to train the ANN to select the thermodynamic property model for the industrial process by determining a deviation of generated process data from different groups of thermodynamic property models.

17. A computing device, comprising:
a processing resource; and
a memory resource storing non-transitory machine-readable instructions to cause the processing resource to:
receive data comprising a type of industrial process and current operating parameter information for the industrial process;
input the data and historical operating parameter information for the industrial process to an artificial neural network (ANN);
select, via the ANN, a thermodynamic property model from a plurality of thermodynamic property models for simulating the industrial process based on the data and the historical operating parameter information;
simulate the industrial process utilizing the current operating parameter information and the selected thermodynamic property model from the ANN; and
generate a flow sheet for the industrial process based on the simulated industrial process.

18. The computing device of claim 17, wherein the flow sheet includes a simulated mass balance and a simulated energy balance for an energy flow in the industrial process.

19. The computing device of claim 17, wherein the flow sheet illustrates an arrangement of equipment for the industrial process and connections between the equipment for the industrial process.

20. The computing device of claim 17, wherein the processing resource is configured to train the ANN to select the thermodynamic property model by training regression models for the plurality of thermodynamic property models to determine a deviation of each thermodynamic property model of the plurality of thermodynamic property models from experimental data.
